(19) United States
(12) Patent Application Publication
(10) Pub. No.: US 2026/0250529 A1
(43) Pub. Date: Aug. 27, 2026

(54) COMPOSITION FOR ENCAPSULATING ORGANIC LIGHTEMITTING DEVICE, AND ORGANIC LIGHT-EMITTING DEVICE DISPLAY APPARATUS COMPRISING ORGANIC LAYERS FORMED THEREFROM DEVICE DISPLAY APPARATUS COMPRISING ORGANIC LAYERS FORMED THEREFROM

(71) Applicant: SAMSUNG SDI CO., LTD., Yongin-si, Gyeonggi-do (KR)

(72) Inventors: Seong Ryong NAM, Suwon-si, Gyeonggi-do (KR); Myong Sook HAN, Suwon-si, Gyeonggi-do (KR); Se II OH, Suwon-si, Gyeonggi-do (KR); Jung Chul LEE, Suwon-si, Gyeonggi-do (KR); Jee Hyun RYU, Suwon-si, Gyeonggi-do (KR)

(21) Appl. No.: 19/104,506

(22) PCT Filed: Aug. 16, 2023
(86) PCT No.: PCT/KR2023/012095

§ 371 Date: Feb. 18, 2025

(30) Foreign Application Priority Data
Aug. 17, 2022 (KR) 10-2022-0102502

(51) Int. Cl. C09D 11/30; C08F 283/12; H10K 50/844

(52) U.S. Cl. CPC C09D 11/30; C08F 283/124; H10K 50/844; C08F 2800/20

(57) ABSTRACT

Provided are a composition for encapsulating an organic light-emitting device, and an organic light-emitting device display apparatus comprising organic layers formed therefrom, the composition comprising: (A) a radiation-curable multifunctional monomer; (B) a radiation-curable monofunctional monomer; (C) a silsesquioxane having one or two radiation-curable functional groups and a substituted or unsubstituted alkyl group; and (D) a photopolymerization initiator, wherein, on the basis of 100 parts by weight of the total amount of (A), (B), (C) and (D), the composition comprises 20-70 parts by weight of (A), 10-60 parts by weight of (B) and 5-50 parts by weight of (C).

### TECHNICAL FIELD

The present invention relates to a composition for encapsulation of an organic light emitting device and an organic light emitting device display including an organic layer formed therefrom.

### BACKGROUND ART

An organic light emitting device can be easily damaged and suffer from deterioration in reliability due to loss of functions thereof upon contact with external moisture or oxygen. Therefore, the organic light emitting device must be encapsulated by an encapsulation layer including an inorganic layer and an organic layer formed of a composition for encapsulation of an organic light emitting device.

The encapsulation layer may have a structure in which organic layers and inorganic layers are repeatedly formed. For example, the encapsulation layer is formed by repeatedly forming organic layers and inorganic layers, for example, in the sequence of an organic layer-inorganic layer-organic layer-inorganic layer, and the like, on an organic light emitting device. Unlike the organic layer, the inorganic layer may be formed of inorganic materials. Generally, the inorganic layer may be formed by a plasma process, a vacuum process, such as sputtering, chemical vapor deposition, plasma chemical vapor deposition, evaporation, sublimation, electron cyclotron resonance vapor deposition, and combinations thereof.

The background technique of the present invention is disclosed in Korean Patent Laid-open Publication No. 10-2016-0150255 and the like.

### DISCLOSURE

### Technical Problem

It is one aspect of the present invention to provide a composition for encapsulation of an organic light emitting device that provides an organic layer with significantly low dielectric constant over a broad frequency range after curing.

It is another aspect of the present invention to provide a composition for encapsulation of an organic light emitting device that has good inkjet processability.

It is a further aspect of the present invention to provide a composition for encapsulation of an organic light emitting device that has high photocuring rate.

It is yet another aspect of the present invention to provide a composition for encapsulation of an organic light emitting device that realizes an organic layer having good post-curing pencil hardness.

### Technical Solution

One aspect of the present invention relates to a composition for encapsulation of an organic light emitting device.

1. The composition for encapsulation of an organic light emitting device includes: (A) a photocurable polyfunctional monomer; (B) a photocurable monofunctional monomer; (C) a silsesquioxane having one or two photocurable functional groups and at least one substituted or unsubstituted alkyl group; and (D) a photopolymerization initiator, wherein the composition includes, based on the sum total of 100 parts by weight of (A), (B), (C) and (D), 20 parts by weight to 70 parts by weight of (A), 10 parts by weight to 60 parts by weight of (B), and 5 parts by weight to 50 parts by weight of (C).

2. In 1, the silsesquioxane (C) may be represented by Formula 5.

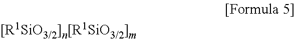

(In Formula 5
R², R¹, n, and m are as defined in the detailed description.)

3. In 1 to 2, the silsesquioxane (C) may have a polyhedral oligomeric silsesquioxane (POSS) structure represented by Formula 7.

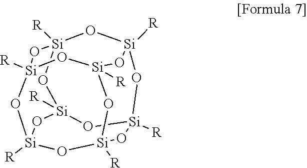

(In Formula 7, Rs are as defined in the detailed description.)

4. In 1 to 3, R² of Formula 5 may include at least one selected from among an isobutyl group, a neopentyl group, an isooctyl group, a 2,4,4-trimethylpentyl group, a dodecyl group, an octadecyl group, and an isooctadecyl group.

5. In 1 to 4, the photocurable polyfunctional monomer (A) may be present in an amount of 50 parts by weight to 450 parts by weight relative to 100 parts by weight of the silsesquioxane (C).

6. In 1 to 5, the photocurable polyfunctional monomer (A) may include at least one of a silicone-free photocurable polyfunctional monomer and a silicone-based photocurable polyfunctional monomer.

7. In 6, the silicone-free photocurable polyfunctional monomer may include at least one of di- to deca-functional (meth)acrylates.

8. In 6 and 7, the silicone-based photocurable polyfunctional monomer may be represented by Formula 1.

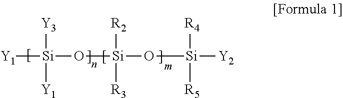

(In Formula 1,

R₁, R₂, R₃, R₄, R₅, Y₁, Y₂, and Y₃ are as defined in the detailed description.)

9. In 1 to 8, the silicone-based photocurable polyfunctional monomer may include at least one of compounds represented by Formulas 1-1, 1-2, and 1-3.

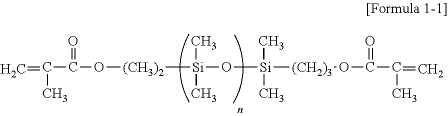

(In Formula 1-1, R₇ is hydrogen or a methyl group and n ranges from 0 to 20.)

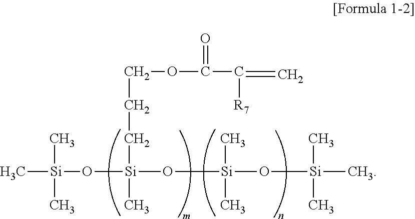

(In Formula 1-2, R₇ is hydrogen or a methyl group, n ranges from 2 to 10, and m ranges from 0 to 20.)

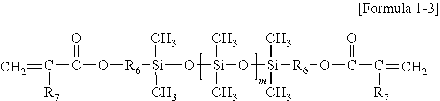

(In Formula 1-3, R₆ is a substituted or unsubstituted C₁ to C₁₀ alkylene group, R₇ is hydrogen or a methyl group, and m ranges from 0 to 20.)

10. In 1 to 9, the photocurable monofunctional monomer (B) may include at least one of a silicone-free photocurable monofunctional monomer or a silicone-based photocurable monofunctional monomer.

11. In 10, the silicone-free photocurable monofunctional monomer may include a mono(meth)acrylate having a substituted or unsubstituted C₁ to C₂₀ straight or branched alkyl group.

12. In 10 to 11, the silicone-based photocurable monofunctional monomer may be represented by Formula 3.

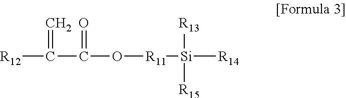

(In Formula 3,
R₁₁, R₁₂, R₁₃, R₁₄, and R₁₅ are as defined in the detailed description.)

In 1 to 12, the silicone-based photocurable monomer may include at least one of compounds represented by Formulas 3-1 to 3-4.

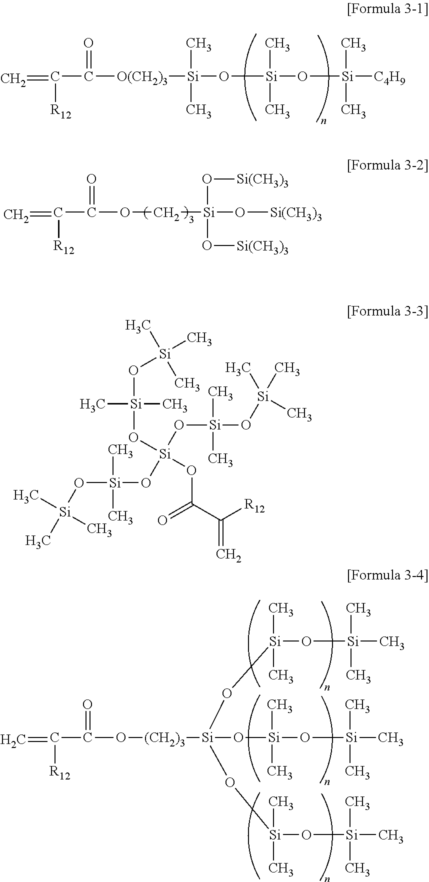

(In Formulas 3-1 to 3-4, R₁₂ and n are as defined in Formulas 3 and 4.)

14. In 1 to 13, the photopolymerization initiator (D) may be present in an amount of 1 part by weight to 5 parts by weight based on the sum total of 100 parts by weight of (A), (B), (C), and (D).

Another aspect of the present invention relates to an organic light emitting device display including an organic layer formed of the composition for encapsulation of an organic light emitting device according to the present invention.

### Advantageous Effects

The present invention provides provide a composition for encapsulation of an organic light emitting device that provides an organic layer having significantly low dielectric constant over a broad frequency range after curing.

The present invention provides a composition for encapsulation of an organic light emitting device that has good inkjet processability.

The present invention provides a composition for encapsulation of an organic light emitting device that has high photocuring rate.

The present invention provides a composition for encapsulation of an organic light emitting device that realizes an organic layer having good post-curing pencil hardness.

### DESCRIPTION OF DRAWINGS

FIG. 1 is a sectional view of an organic light emitting device display according to one embodiment of the present invention.

FIG. 2 is a sectional view of an organic light emitting device display according to another embodiment of the present invention.

### BEST MODE

Hereinafter, embodiments of the present invention will be described in detail with reference to the accompanying drawings to provide a thorough understanding of the invention to those skilled in the art. It should be understood that the present invention may be embodied in different ways and is not limited to the following embodiments. In the drawings, portions irrelevant to the description will be omitted for clarity, and like components will be denoted by like reference numerals throughout the specification. Although lengths, thicknesses or widths of various components may be exaggerated for understanding in the drawings, the present invention is not limited thereto.

The terminology used herein is for the purpose of describing exemplary embodiments and is not intended to limit the invention. As used herein, the singular forms “a”, “an”, and “the” are intended to include the plural forms as well, unless the context clearly indicates otherwise.

As used herein, “(meth)acryl” may refer to “acryl” and/or “methacryl”.

As used herein, unless stated otherwise, “substituted” means that at least one hydrogen atom of a functional group is substituted with a halogen (F, Cl, Br or I), a hydroxyl group, a nitro group, a cyano group, an imino group (=NH, =NR, R being a C₁ to C₁₀ alkyl group), an amino group (—NH₂, —NH(R′), —N(R″)(R′″), R′, R″ and R′″ being each independently a C₁ to C₁₀ alkyl group), an amidino group, a hydrazine or hydrazone group, a carboxyl group, a C₁ to C₂₀ alkyl group, a C₆ to C₃₀ aryl group, a C₃ to C₃₀ cycloalkyl group, a C₃ to C₃₀ heteroaryl group, or a C₂ to C₃₀ heterocycloalkyl group.

As used herein to represent a specific numerical range, “X to Y” means greater than or equal to X and less than or equal to Y (X≤ and ≤Y).

A composition for encapsulation of an organic light emitting device according to one embodiment of the present invention (referred to hereinafter as “composition”) can form an organic layer with a significantly low dielectric constant over a broad frequency range and has excellent inkjet processability. In one embodiment, the frequency range may be from 100 kHz to 1,000 kHz.

An organic layer formed by curing the composition according to the present invention may have a dielectric constant of 2.80 or less, for example, 2.00 to 2.80, or 2.40 to 2.80, in a broad frequency range. Within this range, the composition can efficiently realize performance of an organic light emitting device without being affected by external static electricity or electricity.

Herein, “good inkjet processability” means that when the composition is applied by an inkjet printer, the composition has good spreadability to form an organic layer having a uniform thickness without agglomeration. Good inkjet processability results in a uniform thickness of the organic layer, thereby improving screen quality in operation of a display device.

Herein, when elements shown in [ ] and ( ) appear multiple times in a certain formula, the elements may be the same or different from each other.

The compositions according to the present invention includes: (A) a photocurable polyfunctional monomer; (B) a photocurable monofunctional monomer; (C) a silsesquioxane having one or two photocurable functional groups and at least one substituted or unsubstituted alkyl group; and (D) a photopolymerization initiator, wherein (A), (B), and (C) are present in amounts described below. The composition according to the present invention can easily provide good inkjet processability and can realize an organic layer that has a significantly low dielectric constant, high photocuring rate, and high post-curing pencil hardness.

Hereinafter, each component of the composition according to embodiments of the present invention will be described in detail.

### Photocurable Polyfunctional Monomer

The photocurable polyfunctional monomer (A) serves to reduce post-curing dielectric constant of the composition while improving inkjet processability together with the silsesquioxane having one or two photocurable functional groups and at least one substituted or unsubstituted alkyl group (C) described below.

In terms of inkjet processability, the photocurable polyfunctional monomer (A) is present in a suitable amount relative to the silsesquioxane having one or two photocurable functional groups and at least one substituted or unsubstituted alkyl group (C). Relative to 100 parts by weight of the silsesquioxane having one or two photocurable functional groups and at least one substituted or unsubstituted alkyl group (C), the photocurable polyfunctional monomer (A) may be present in an amount of 50 parts by weight to 450 parts by weight, specifically 50, 55, 60, 65, 70, 75, 80, 85, 90, 95, 100, 105, 110, 115, 120, 125, 130, 135, 140, 145, 150, 155, 160, 165, 170, 175, 180, 185, 190, 195, 200, 205, 210, 215, 220, 225, 230, 235, 240, 245, 250, 255, 260, 265, 270, 275, 280, 285, 290, 295, 300, 305, 310, 315, 320, 325, 330, 335, 340, 345, 350, 355, 360, 365, 370, 375, 380, 385, 390, 395, 400, 405, 410, 415, 420, 425, 430, 435, 440, 445, or 450 parts by weight, preferably 100 parts by weight to 400 parts by weight. Within this range, the photocurable polyfunctional monomer can assist in improvement in inkjet processability of the composition.

In one embodiment, the photocurable polyfunctional monomer (A) may be a non-aromatic monomer free from an aromatic group.

The photocurable polyfunctional monomer (A) may include a monomer having photocurable functional groups, for example, at least two (meth)acrylate groups, for example, two to ten (meth)acrylate groups.

The photocurable polyfunctional monomer (A) may include at least one of a silicone-free photocurable polyfunctional monomer that does not have silicone, or a silicone-based photocurable polyfunctional monomer that has silicone. Each of the silicone-free photocurable polyfunctional monomer and the silicone-based photocurable polyfunctional monomer may be included singularly or in plural in the composition.

The silicone-free photocurable polyfunctional monomer includes bi- to deca-functional (meth)acrylates, specifically a di(meth)acrylate having a substituted or unsubstituted C₁ to C₂₀ straight or branched alkylene group, a substituted or unsubstituted C₃ to C₂₀ tri(meth)acrylate of triol, tetraol, pentaol or hexaol, a tetra(meth)acrylate, a penta(meth)acrylate, or a hexa(meth)acrylate.

For example, the di(meth)acrylate may include at least one selected from among hexanediol di(meth)acrylate, heptanediol di(meth)acrylate, octanediol di(meth)acrylate, nonanediol di(meth)acrylate, decanediol di(meth)acrylate, undecanediol di(meth)acrylate, dodecanediol di(meth)acrylate including 1,12-dodecanediol di(meth)acrylate and the like, and tetradecanediol di(meth)acrylate including 1,14-tetradecanediol di(meth)acrylate and the like. The tri(meth)acrylate may include C₃ to C₂₀ tri(meth)acrylates of triol, tetraol, pentaol or hexaol, including trimethylolpropane tri(meth)acrylate, pentaerythritol tri(meth)acrylate, dipentaerythritol tri(meth)acrylate, tris(2-hydroxyethyl)isocyanurate tri(meth)acrylate, and the like. The tetra(meth)acrylate may include C₄ to C₂₀ tetra(meth)acrylates of tetraol, pentaol or hexaol including pentaerythritol tetra(meth)acrylate, dipentaerythritol tetra(meth)acrylate, ditrimethylolpropane tetra(meth)acrylate, and the like. The penta(meth)acrylate may include C₄ to C₂₀ penta(meth)acrylates of pentaol or hexaol, including dipentaerythritol penta(meth)acrylate and the like. The hexa(meth)acrylate may include C₄ to C₂₀ hexa(meth)acrylates of hexaol, including dipentaerythritol hexa(meth)acrylate and the like.

The silicone-based photocurable polyfunctional monomer is a monomer having silicone, particularly a monomer having a siloxane group (*—Si—O—Si—*), in which photocurable functional groups may be bonded to both ends or side chains of the monomer.

In one embodiment, the silicone-based photocurable polyfunctional monomer may be represented by Formula 1.

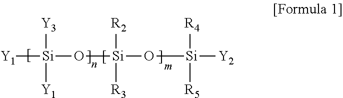

(In Formula 1,
R₁, R₂, R₃, R₄, and R₅ are each independently hydrogen, a substituted or unsubstituted C₁ to C₃₀ alkyl group, a substituted or unsubstituted C₁ to C₃₀ alkyl ether group, *—N(R′)(R″) (* being a linking site of an element, and R′ and R″ being identical to or different from each other and being hydrogen or a substituted or unsubstituted C₁ to C₃₀ alkyl group), a substituted or unsubstituted C₁ to C₃₀ alkyl sulfide group, a substituted or unsubstituted C₆ to C₃₀ aryl group, or a substituted or unsubstituted C₇ to C₃₀ arylalkyl group;
Y₁, Y₂, and Y₃ are each independently a substituted or unsubstituted C₁ to C₃₀ alkyl group, a substituted or unsubstituted C₁ to C₁₀ monoalkylsilyloxy group, a substituted or unsubstituted C₁ to C₁₀ dialkylsilyloxy group, a substituted or unsubstituted C₁ to C₁₀ trialkylsilyloxy group, or a compound represented by Formula 2:

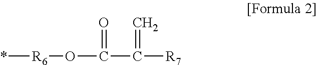

(in Formula 2,
* is a linking site of an element,
R₆ is a substituted or unsubstituted C₁ to C₁₀ alkylene group, and
R₇ is hydrogen or a methyl group); and
n ranges from 0 to 20, m ranges from 0 to 20, and n+m is greater than 0,
Y₁ and Y₂ being Formula 2, or
Y₃ being Formula 2 and n ranging from 2 to 20.)

In Formula 1, C₁ to C₁₀ of the substituted or unsubstituted C₁ to C₁₀ monoalkylsilyloxy group refers to the number of carbon atoms contained in one alkyl group. In Formula 1, C₁ to C₁₀ of the substituted or unsubstituted C₁ to C₁₀ dialkylsilyloxy group refers to the number of carbon atoms contained in one alkyl group. In Formula 1, C₁ to C₁₀ of the substituted or unsubstituted C₁ to C₁₀ trialkylsilyloxy group refers to the number of carbon atoms contained in one alkyl group.

Preferably, R₁, R₂, R₃, R₄, and R₅ are each independently a substituted or unsubstituted C₁ to C₁₀ alkyl group, a substituted or unsubstituted C₁ to C₅ alkyl group, or a substituted or unsubstituted C₁ to C₃ alkyl group.

Preferably, R₆ is a substituted or unsubstituted C₁ to C₅ alkylene group or a substituted or unsubstituted C₁ to C₃ alkylene group.

In Formula 1, each of n and m may be an average value or an integer in the range of 0 to 10, or 0 to 5.

For example, the silicone-based photocurable polyfunctional monomer may include at least one selected from among (meth)acryloxypropyl terminated polydimethylsiloxane (e.g.: Formula 1-1), (meth)acryloxypropylmethylsiloxane dimethylsiloxane (e.g.: Formula 1-2), and (meth)acrylic modified reactive silicone fluids (e.g.: Formula 1-3).

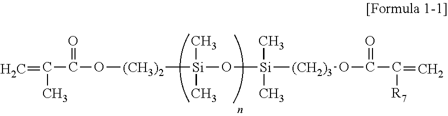

(In Formula 1-1, R₇ is hydrogen or a methyl group and n ranges from 0 to 20.)

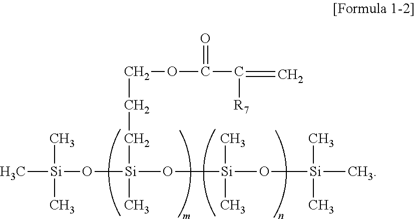

(In Formula 1-2, R₇ is hydrogen or a methyl group, n ranges from 2 to 10, and m ranges from 0 to 20.)

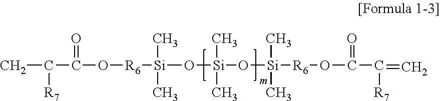

(In Formula 1-3, R₆ is a substituted or unsubstituted C₁ to C₁₀ alkylene group, R₇ is hydrogen or a methyl group, and m ranges from 0 to 20.)

The silicone-based photocurable polyfunctional monomer may be obtained from commercially available products or may be prepared by any typical methods known to those skilled in the art.

The photocurable polyfunctional monomer (A) may be present in an amount of 20 parts by weight to 70 parts by weight based on the sum total of 100 parts by weight of (A), (B), (C), and (D). Within this range, the composition can form a film through photo-curing. Specifically, the photocurable polyfunctional monomer (A) may be present in an amount of 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, or 70 parts by weight, preferably 30 parts by weight to 60 parts by weight.

The photocurable polyfunctional monomer (A) may be present in an amount of 95 parts by weight or more, for example, 99 parts by weight to 100 parts by weight, or 100 parts by weight, based on the sum total of 100 parts by weight of all photocurable polyfunctional monomers contained in the composition. Within this range, the composition can easily realize the effects of the invention.

### Photocurable Monofunctional Monomer

The photocurable monofunctional monomer (B) can assist in increase in hardness of the organic layer after curing of the composition and can help formation of a matrix of the organic layer.

In one embodiment, the photocurable monofunctional monomer (B) may include a non-aromatic monomer that does not have an aromatic group.

The photocurable monofunctional monomer (B) may include a monomer having at least one photocurable functional group, for example, at least one (meth)acrylate group.

The photocurable monofunctional monomer (B) may include at least one of a silicone-free photocurable monomer or a silicone-based photocurable monomer that has silicone. Each of the silicone-free photocurable monomer and the silicone-based photocurable monomer may be present singularly or in plural.

The silicone-free photocurable monofunctional monomer may include mono(meth)acrylates having a substituted or unsubstituted C₁ to C₂₀ straight or branched alkyl group. For example, the silicone-free photocurable monofunctional monomer may include at least one selected from among octyl (meth)acrylate, nonyl (meth)acrylate, lauryl (meth)acrylate, undecyl (meth)acrylate, dodecyl (meth)acrylate, tridecyl (meth)acrylate, substituted tetradecyl (meth)acrylates including tetradecyl (meth)acrylate, 2-decyl-1-tetradecyl (meth)acrylate and the like, and isostearyl (meth)acrylate.

Preferably, the silicone-free photocurable monofunctional monomer includes a mono(meth)acrylate having a substituted or unsubstituted C₁₀ to C₂₀ alkyl group, more preferably a mono(meth)acrylate having a substituted or unsubstituted C₁₀ to C₁₅ alkyl group.

The silicone-based photocurable monofunctional monomer may be a monomer having silicone, particularly a monomer having a siloxane group (*—Si—O—Si—*). In one embodiment, the silicone-based photocurable monofunctional monomer may be represented by Formula 3.

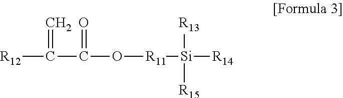

(In Formula 3,
R₁₁ is a single bond or a substituted or unsubstituted C₁ to C₁₀ alkylene group,
R₁₂ is hydrogen or a methyl group, and
R₁₃, R₁₄, and R₁₅ are each independently hydrogen, a substituted or unsubstituted C₁ to C₃₀ alkyl group, a substituted or unsubstituted C₁ to C₃₀ alkylether, *—N(R′)(R″) (* being a linking site of an element, R′ and R″ being identical to or different from each other and being hydrogen or a substituted or unsubstituted C₁ to C₃₀ alkyl group), a substituted or unsubstituted C₁ to C₃₀ alkyl sulfide group, a substituted or unsubstituted C₆ to C₃₀ aryl group, a substituted or unsubstituted C₇ to C₃₀ arylalkyl group, a substituted or unsubstituted C₁ to C₁₀ monoalkylsilyloxy group, a substituted or unsubstituted C₁ to C₁₀ dialkylsilyloxy group, a substituted or unsubstituted C₁ to C₁₀ trialkylsilyloxy group, a substituted or unsubstituted C₁ to C₁₀ monoalkylsilyl group, a substituted or unsubstituted C₁ to C₁₀ dialkylsilyl group, a substituted or unsubstituted C₁ to C₁₀ trialkylsilyl group, or a compound represented by Formula 4.)

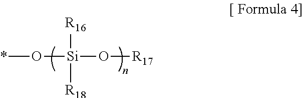

(In Formula 4,
* is a linking site of an element,
R₁₆, R₁₇, and R₁₈ are each independently hydrogen, a substituted or unsubstituted C₁ to C₁₀ alkyl group, a substituted or unsubstituted C₁ to C₁₀ monoalkylsilyl group, a substituted or unsubstituted C₁ to C₁₀ dialkylsilyl group, a substituted or unsubstituted C₁ to C₁₀ trialkylsilyl group, a substituted or unsubstituted C₁ to C₁₀ monoalkylsilyloxy group, a substituted or unsubstituted C₁ to C₁₀ dialkylsilyloxy group, or a substituted or unsubstituted C₁ to C₁₀ trialkylsilyloxy group, and
n is an integer of 1 to 20.)

In Formulas 3 and 4, C₁ to C₁₀ of the substituted or unsubstituted C₁ to C₁₀ monoalkylsilyloxy or monoalkylsilyl group refers to the number of carbon atoms contained in one alkyl group. In Formulas 3 and 4, C₁ to C₁₀ of the substituted or unsubstituted C₁ to C₁₀ dialkylsilyloxy or dialkylsilyl group refers to the number of carbon atoms contained in one alkyl group. In Formulas 3 and 4, C₁ to C₁₀ of the substituted or unsubstituted C₁ to C₁₀ trialkylsilyloxy or trialkylsilyl group refers to the number of carbon atoms contained in one alkyl group.

Preferably, R₁ is a substituted or unsubstituted C₁ to C₅ alkylene group.

Preferably, R₁₃, R₁₄, and R₁₅ are each independently a substituted or unsubstituted C₁ to C₅ alkyl group or the compound represented by Formula 4. In Formula 4, R₁₆, R₁₇, and R₁₈ may be each independently a substituted or unsubstituted C₁ to C₅ alkyl group.

For example, the silicone-based photocurable monofunctional monomer may include at least one selected from among mono(meth)acryloxypropyl terminated polydimethylsiloxane (e.g.: Formula 3-1), (3-(meth)acryloyloxy)propyltris(trimethylsiloxy)silane (e.g.: Formula 3-2), (3-(meth)acryloxypropyl)tris(pentamethyldisiloxy)silane (e.g.: Formula 3-3), and (meth)acryloxypropyl T-structured siloxane (e.g.: Formula 3-4).

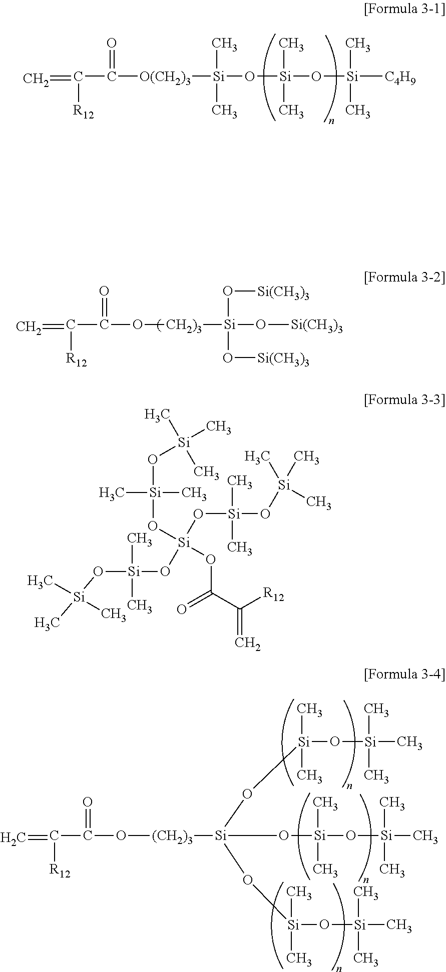

(In Formulas 3-1 to 3-4, R₁₂ and n are as defined in Formulas 3 and 4.)

The photocurable monofunctional monomer (B) may be obtained from commercially available products or may be prepared by any typical methods known to those skilled in the art.

The photocurable monofunctional monomer (B) is present in an amount of 10 parts by weight to 60 parts by weight based on the sum total of 100 parts by weight of (A), (B), (C), and (D). Within this range, the composition can secure low dielectric constant. For example, the photocurable monofunctional monomer (B) may be present in an amount of 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, or 60 parts by weight, preferably 20 parts by weight to 50 parts by weight.

### (C) Silsesquioxane Having One or Two Photocurable Functional Groups and at Least One Substituted or Unsubstituted Alkyl Group

The silsesquioxane having one or two photocurable functional groups and at least one substituted or unsubstituted alkyl group (C) can form an organic layer having a significantly low dielectric constant over a broad frequency range after curing. The composition according to the present invention employs silsesquioxane to reduce the dielectric constant of the organic layer and also improves inkjet processability while reducing the dielectric constant of the organic layer using the silsesquioxane having one or two photocurable functional groups and at least one substituted or unsubstituted alkyl group together with the photocurable polyfunctional monomers.

The silsesquioxane has a photocurable functional group, for example a (meth)acrylate group, in which the photocurable functional group may be directly bonded to silicon of the silsesquioxane or indirectly bonded thereto through, for example, a substituted or unsubstituted C₁ to C₁₀ group. The alkyl groups of the silsesquioxane may include substituted or unsubstituted C₃ to C₁₀ straight or branched alkyl groups and may be directly bonded to silicon of the silsesquioxane.

In one embodiment, the photocurable functional groups may be directly bonded to one or two silicon atoms of the silsesquioxane and the substituted or unsubstituted alkyl groups may be bonded to remaining silicon atoms thereof.

In one embodiment, the silsesquioxane may be a non-aromatic silsesquioxane that does not have an aromatic group.

In one embodiment, the silsesquioxane may be represented by Formula 5.

[R¹SiO_{3/2}]ₙ[R²SiO₃/2]ₘ [Formula 5]

(In Formula 5,
R² is a substituted or unsubstituted C₁ to C₂₀ straight or branched alkyl group,
R¹ is represented by Formula 6:

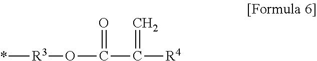

(in Formula 6,
* is a linking site to silicon,
R³ is a substituted or unsubstituted C₁ to C₁₀ alkylene group, and
R⁴ is hydrogen or a methyl group),
n is 1 or 2, and m is greater than 0 and less than or equal to 10.)

Preferably, R² is a substituted or unsubstituted C₄ to C₂₀ straight or branched alkyl group. For example, R² may be at least one selected from among an isobutyl group, a neopentyl group, an isooctyl group, a 2,4,4-trimethylpentyl group, a dodecyl group, an octadecyl group, and an isooctadecyl group.

Preferably, R³ is a substituted or unsubstituted C₁ to C₆ alkylene group or a substituted or unsubstituted C₁ to C₅ alkylene group.

The silsesquioxane may have an open cage structure, a ladder structure, or a random structure, preferably a polyhedral oligomeric silsesquioxane (POSS) structure represented by Formula 7.

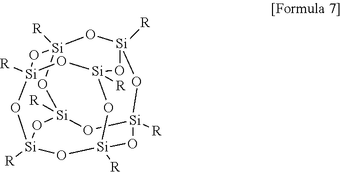

(In Formula 7,
one or two Rs are R¹, and
six to seven Rs are R₂
R¹ and R² being as defined in Formula 5.)

For example, the silsesquioxane may include at least one of Formula 7-1 or Formula 7-2.

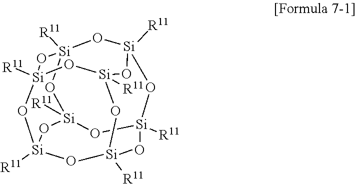

(In Formula 7-1,
one or two R¹¹ are

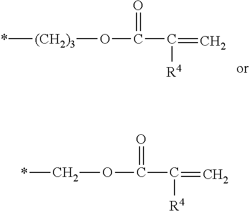

(R⁴ being hydrogen or a methyl group), and
six or seven R¹¹ are *—CH₂—CH(CH₃)—CH₂—C(CH₃)₃)

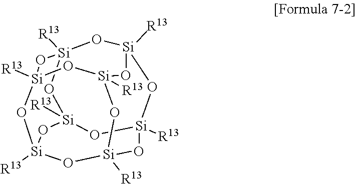

(In Formula 7-2,
one or two R¹³ is

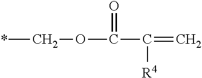

(R⁴ being hydrogen or a methyl group), and
six or (to?) eight R¹³ are *—CH₂—CH(CH₃)₂).

The silsesquioxane may be obtained from commercially available products or may be prepared by any typical methods known to those skilled in the art.

The silsesquioxane having one or two photocurable functional groups and a substituted or unsubstituted alkyl group is present in an amount of 5 parts by weight to 50 parts by weight based on the sum total of 100 parts by weight of (A), (B), (C) and (D). Within this range, the silsesquioxane can assist in reduction in dielectric constant. Specifically, the silsesquioxane may be present in an amount of 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50 parts by weight. Preferably, the silsesquioxane is present in an amount of 10 parts by weight to 35 parts by weight.

In the composition, (A), (B), and (C) may be present in a total amount of 90 parts by weight or less, preferably 90 parts by weight to 99 parts by weight. Within this range, the composition can easily realize the effects of the present invention.

The photocurable monomer (B) and the silsesquioxane having one or two photocurable functional groups and at least one substituted or unsubstituted alkyl group (C) may be present in a total amount of 95 parts by weight or more, preferably 99 parts by weight to 100 parts by weight, more preferably 100 parts by weight, based on 100 parts by weight of all of the photocurable monomers in the composition. Within this range, the composition can easily realize the effects of the present invention.

### (D) Photopolymerization Initiator

The photopolymerizable initiator may include any typical photopolymerizable initiator that can perform photocuring reaction. For example, the photopolymerizable initiator may include a triazine initiator, an acetophenone initiator, a benzophenone initiator, a thioxanthone initiator, a benzoin initiator, a phosphorus initiator, an oxime initiator, or a mixture thereof.

Preferably, the photopolymerizable initiator includes a phosphorus initiator having a maximum absorption wavelength of 360 nm to 400 nm. In the composition according to the present invention, the phosphorus initiator can secure better initiation performance under long wavelength UV light (for example, 300 nm to 400 nm). The phosphorus initiator may include diphenyl (2,4,6-trimethylbenzoyl)phosphine oxide, phenyl bis(2,4,6-trimethylbenzoyl)phosphine oxide, 2,4,6-trimethylbenzoyl diphenylphosphinate, or a mixture thereof. For example, these initiators may be used alone or as a mixture thereof. The “maximum absorption wavelength” may be measured by a typical method known to those skilled in the art or may be a value obtained with reference to a product catalog.

The photopolymerization initiator may be present in an amount of 1 part by weight to 10 parts by weight, preferably 1 part by weight to 5 parts by weight, based on the sum total of 100 parts by weight of (A), (B), (C) and (D). Within this range, the composition can have high photocuring rate and can prevent deterioration in light transmittance due to remaining initiator.

The composition according to the present invention may be prepared by mixing (A), (B), (C), and (D). For example, the compositions according to the present invention may be prepared in the form of a solvent-free composition.

The composition according to the present invention is a photocurable composition and may be cured to form an encapsulation layer upon irradiation with UV light at 10 mW/cm² to 500 mW/cm² for 1 second to 50 seconds.

The composition according to the present invention may further include typical additives known to those skilled in the art. The additives may include a heat stabilizer, an antioxidant, and a UV absorbent, without being limited thereto.

The composition according to the present invention may have a viscosity of 7 cP to 100 cP, preferably 7 cP to 60 cP, more preferably 7 cP to 50 cP, at 25±2° C. (23° C. to 27° C.). Within this range, the composition can exhibit good ink-jetting properties.

The composition according to the present invention may have a photocuring rate of 90% to 100%, preferably 91% to 99%, more preferably 91% to 93%. Within this range, a cured product of the composition can act as an organic layer. The photocuring rate can be calculated according to Equation 2.

The organic layer formed by photocuring of the composition according to the present invention may have a pencil hardness of 4B or higher, for example, 4B to B.

The composition according to the present invention may be used for encapsulation of an organic light emitting device. Specifically, the composition may form an organic layer in an encapsulation structure in which inorganic layers and the organic layers are sequentially formed.

The composition according to the present invention may be used for encapsulation of a member for devices, particularly a member for display devices, which may be decomposed or damaged by permeation of gases or liquids in the surrounding environment, for example, oxygen, moisture and/or water vapor in the atmosphere, and chemicals used in processing electronic products. For example, the member for devices may include a lighting device, a metal sensor pad, a microdisk laser, an electrochromic device, a photochromic device, a microelectromechanical system, a solar cell, an integrated circuit, a charge coupled device, and a luminous polymer, without being limited thereto.

An organic light emitting device display according to the present invention may include an organic layer formed of the composition for encapsulation of an organic light emitting device according to the embodiments. Specifically, the organic light emitting device display may include an organic light emitting device; and a barrier stack formed on the light emitting device and including an inorganic layer and an organic layer, which may be formed of the composition for encapsulation of an organic light emitting device according to the embodiments of the present invention. As a result, the organic light emitting device display can exhibit good reliability.

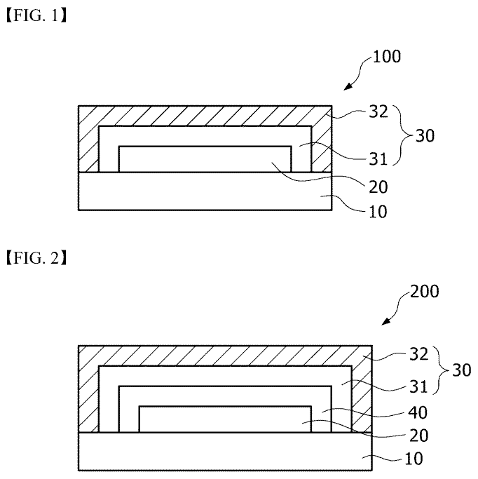

Next, an organic light emitting device display according to one embodiment of the invention will be described with reference to FIG. 1. FIG. 1 is a sectional view of an organic light emitting device display according to one embodiment of the present invention.

Referring to FIG. 1, an organic light emitting device display 100 includes a substrate 10, an organic light emitting device 20 formed on the substrate 10, and a barrier stack 30 formed on the organic light emitting device 20 and including an inorganic layer 31 and an organic layer 32, wherein the inorganic layer 31 adjoins the organic light emitting device 20 and the organic layer 32 may be formed of the composition for encapsulation of an organic light emitting device according to the embodiments of the present invention.

The substrate 10 is not limited to a particular substrate so long as an organic light emitting device may be formed on the substrate. For example, the substrate 10 may be formed of a material, such as transparent glass, a plastic sheet, and a silicon or metal substrate.

The organic light emitting device 20 is commonly used in an organic light emitting device display, and, although not shown in FIG. 1, may include a first electrode, a second electrode, and an organic light emitting layer formed between the first electrode and the second electrode. The organic light emitting layer may have a structure wherein a hole injection layer, a hole transport layer, a light emitting layer, an electron transport layer, and an electron injection layer are sequentially stacked, without being limited thereto.

The barrier stack 30 includes the inorganic layer and the organic layer, which may be composed of different components, thereby realizing a function of encapsulating the organic light emitting device.

The inorganic layer includes different components than the organic layer, thereby supplementing the effects of the organic layer. For example, the inorganic layer may include at least one selected from among metals; nonmetals; compounds or alloys of metals; compounds or alloys of nonmetals; oxides of metals or nonmetals; fluorides of metals or nonmetals; nitrides of metals or nonmetals; carbides of metals or nonmetals; oxynitrides of metals or nonmetals; borides of metals or nonmetals; oxyborides of metals or nonmetals; silicides of metals or nonmetals; and mixtures thereof. The metals or nonmetals may include silicon (Si, aluminum (Al), selenium (Se), zinc (Zn), antimony (Sb), indium (In), germanium (Ge), tin (Sn), bismuth (Bi), transition metals, and lanthanide metals, without being limited thereto. Specifically, the inorganic layer may include silicon oxide (SiOₓ), silicon nitride (SiNₓ), silicon oxynitride (SiOₓN_{y}), zinc selenide (ZnSe), zinc oxide (ZnO), antimony trioxide (Sb₂O₃), aluminum oxide (AlOₓ) including alumina (Al₂O₃), indium oxide (In₂O₃), tin oxide (SnO₂), and the like.

The inorganic layer may be deposited by a plasma process or a vacuum process, for example, sputtering, chemical vapor deposition, plasma chemical vapor deposition, evaporation, sublimation, electron cyclotron resonance-plasma enhanced chemical vapor deposition, or combinations thereof.

The organic and inorganic layers may be alternately deposited to secure smoothing properties of the inorganic layer while preventing defects of one inorganic layer from spreading to other inorganic layers.

The organic layer may be formed by coating, deposition, or curing of the composition for encapsulation of an organic light emitting device, or combinations thereof. For example, the organic layer may be formed by coating the composition to a thickness of 1 μm to 50 μm, followed by curing the composition through irradiation with UV light at 10 mW/cm² to 500 mW/cm² for 1 second to 50 seconds.

The barrier stack may include any number of organic and inorganic layers. Combination of the organic and inorganic layers may vary according to the level of permeation resistance to oxygen and/or moisture and/or water vapor and/or chemicals. For example, the organic and inorganic layers are formed in a total of 10 layers or less, for example, 2 to 7 layers. Specifically, the organic and inorganic layers are formed in a total of 7 layers in the sequence of inorganic layer/organic layer/inorganic layer/organic layer/inorganic layer/organic layer/inorganic layer.

In the barrier stack, the organic layers and the inorganic layers may be alternately deposited. This is because the aforementioned composition has an effect on the organic layer due to the properties thereof. As a result, the organic layers and the inorganic layers can supplement or reinforce encapsulation of the member for the apparatus.

Next, an organic light emitting device display according to another embodiment of the invention will be described with reference to FIG. 2. FIG. 2 is a sectional view of an organic light emitting device display according to another embodiment of the present invention.

Referring to FIG. 2, an organic light emitting device display 200 includes a substrate 10, an organic light emitting device 20 formed on the substrate 10, and a barrier stack 30 formed on the organic light emitting device 20 and including an inorganic layer 31 and an organic layer 32, in which the inorganic layer 31 encapsulates an inner space 40 receiving the organic light emitting device 20 therein and the organic layer 32 may be formed of the composition for encapsulation of an organic light emitting device according to the embodiments of the invention. The organic light emitting device display 200 according to this embodiment is substantially the same as the organic light emitting device display according to the embodiment except that the inorganic layer does not adjoin the organic light emitting device.

### MODE FOR INVENTION

Next, the present invention will be described in more detail with reference to some examples. It should be understood that these examples are provided for illustration only and are not to be construed in any way as limiting the invention.

Details of components used in Examples and Comparative Examples are as follows.

### (A) Photocurable Polyfunctional Monomer

(A1) 1,14-tetradecanediol dimethacrylate (Aldrich)
(A2) (Meth)acryloxypropyl terminated polydimethylsiloxane (DMS-R11, Gelest Inc.)

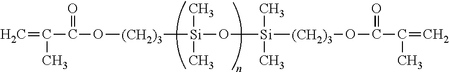

(A3) 1,3-bis(3-methacryloxypropyl)tetramethyldisiloxane (Gelest Inc.)

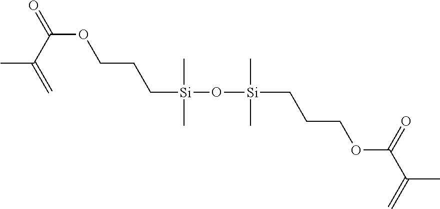 [SMILES: C=C(C)C(=O)OCCC[Si](C)(C)O[Si](C)(C)CCCOC(=O)C(=C)C]

(A4) 1,12-dodecanediol dimethacrylate (Aldrich)
(A5) RMS-083 ((methacryloxypropyl)methylsiloxane-dimethylsiloxane copolymer, n being 2 or more, Gelest Inc.)

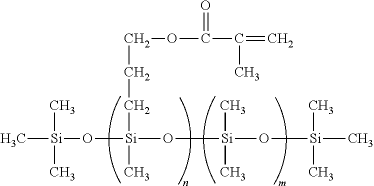

(A6) X-22-2445 (acrylic-modified reactive silicone fluids, Shin-Etsu Chemical Co., Ltd.)

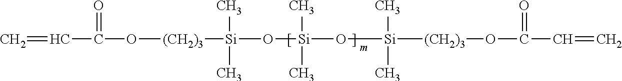

### (B) Photocurable Monofunctional Monomer

(B1) 2-decyl-1-tetradecyl acrylate
(B2) Lauryl acrylate
(B3) Monomethacryloxypropyl terminated polydimethylsiloxane (MCR-M07, Gelest Inc.)

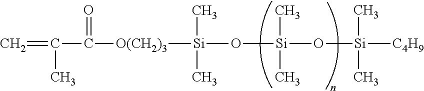

(B4) 3-(methacryloyloxy)propyltris(trimethyloxy)silane

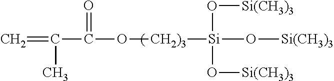

(B5) (3-methacryloxypropyl)tris(pentamethyldisiloxy)silane

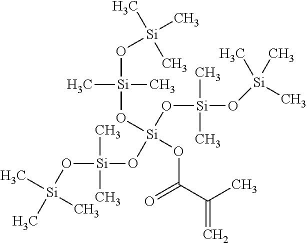

(B36) Methacryloxypropyl T-structure siloxane (RTT-1011, Gelest Inc.)

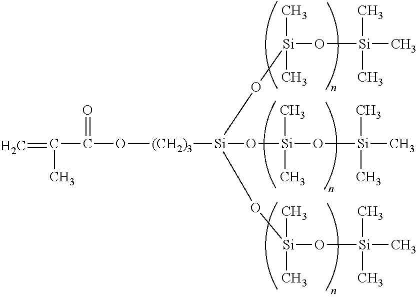

### (C) Silsesquioxane

(C1) MA0719

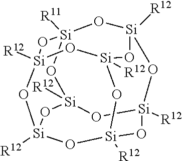

(R₁₁ is

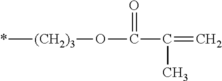

and R₁₂ is *—CH₂—CH (CH₃) CH₂—C(CH₃)₃).
(C2) MAC-SQ SI-20

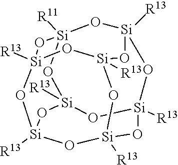

(R₁₁ is

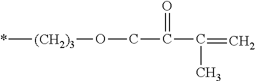

and R₁₃ is *—CH₂—CH₂(CH₃)₂)
(C3) MA0718

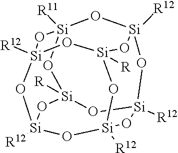

(R₁₁ is

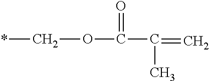 [SMILES: *COC(=O)C(=C)C]

and R₁₂ is *—CH₂—CH(CH₃)—CH₂—C(CH₃)₃)
(C4) MAC-SQ-TM-100

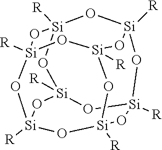

(R is

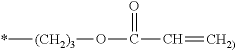

### (D) Photopolymerization Initiator: Phosphorus Initiator (Irgacure TPO)

### Example 1

A composition for encapsulation was prepared by placing 55 parts by weight of (A1), 22 parts by weight of (B1), 20 parts by weight of (C1), and 3 parts by weight of (D) in a 125 ml brown polypropylene botting, followed by mixing at room temperature using a shaker for 3 hours.

### Examples 2 to 10 and Comparative Examples 1 to 4

Each composition was prepared in the same manner as in Example 1 except that the content of each component was changed as listed in Table 1 (unit: parts by weight). In Tables 1 and 2, “-” means that the corresponding component is not present.

For the compositions prepared in Example and Comparative Examples, the following properties were measured and results are shown in Table 1.

(1) Dielectric constant (unit: none): Each of the compositions prepared in Examples and Comparative Examples was coated to a predetermined thickness on a chromium (Cr) plate, followed by curing through UV irradiation at an irradiance of 100 mW/cm² for 10 seconds, thereby forming an 8 μm thick coating film. Aluminum electrodes (electrodes for measurement of dielectric constant) were deposited on the coating film, followed by measurement of a dielectric constant of the coating film using an impedance analyzer (E4990A, Impedance Analyzer) at 200 kHz and 25° C.

(2) Viscosity (unit: cP): Viscosity of each of the compositions prepared in Examples and Comparative Examples was measured at 24.8° C. using a viscometer Spindle No. 40 (LV DV-II Pro, Brookfield Co., Ltd).

(3) Inkjet processability (unit: none): 500 g of each of the compositions of Examples and Comparative Examples was jetted in the form of droplets through an inkjet printer (OMNIJET 300, Konica Minolta KM1024i head, Unijet Co., Ltd.). The inkjet printer had a head temperature of 25° C. Droplet generation and jetting possibility upon ink jetting were evaluated. When a composition formed uniform droplets upon ink jetting and allowed the droplets to spread more than 120% without any problem, the composition was rated as o, and when a composition formed uneven droplets upon ink jetting or did not allow the droplets to spread more than 120%, the composition was rated as x.

(4) Photocuring rate (unit: %): Each of the compositions prepared in Examples and Comparative Examples was measured as to intensity of absorption peaks in the vicinity of 1,635 cm⁻¹ (C=C) and 1,720 cm⁻¹ (C═O) using an FT-IR spectrometer (NICOLET 4700, Thermo Co., Ltd.). Each encapsulation composition was applied to a glass substrate through a sprayer, followed by curing through UV irradiation at 100 mW/cm² for 20 seconds, thereby preparing a specimen having a size of 20 cm×20 cm×3 μm (width×length× thickness). Then, the intensity of absorption peaks of the cured film was measured in the vicinity of 1,635 cm⁻¹ (C=C) and 1,720 cm⁻¹ (C═O) using an FT-IR spectrometer (NICOLET 4700, Thermo Co., Ltd.). Photocuring rate was calculated by Equation 1.

$$Photocuring rate ( \% ) = \vert 1 - ( A / B ) \vert \times 100 \qquad [ Equation 1 ]$$

where A is a ratio of the intensity of an absorption peak in the vicinity of 1,635 cm⁻¹ to the intensity of an absorption peak in the vicinity of 1,720 cm⁻¹, as measured for the cured film, and
B is a ratio of the intensity of an absorption peak in the vicinity of 1,635 cm⁻¹ to the intensity of an absorption peak in the vicinity of 1,720 cm⁻¹, as measured for the composition.

(5) Pencil hardness: A specimen of an organic layer having a thickness of 8 m was prepared by depositing each of the compositions of Examples and Comparative Examples onto a glass substrate, followed by curing the composition through irradiation with UV light at 100 mW/cm² for 10 seconds. Pencil hardness was measured on the specimen. In measurement of pencil hardness, an electric pencil hardness tester (Lab-Q D300A) and pencils of 6B to 9H (Mitsubishi Co., Ltd.) were used. Pencil hardness was measured under the following conditions: a load of 200 g applied from a pencil to the specimen, a scratch angle of 45′ and at a scratch speed of 48 mm/min. When a specimen had one or more scratches upon scratching 5 times using a certain pencil, pencil hardness of the specimen was measured again using another pencil having one-level lower pencil hardness than the previous pencil. A pencil hardness value allowing no scratch to be observed all five times was taken as the maximum pencil hardness.

TABLE 1

| | | Example | Example | Example | Example | Example | Example | Example |
|---|---|---|---|---|---|---|---|---|
| | | 1 | 2 | 3 | 4 | 5 | 6 | 7 |
| (A) | (A1) | 55 | — | — | 50 | 55 | — | — |
| | (A2) | — | 54 | — | — | — | 53 | — |
| | (A3) | — | — | 40 | — | — | — | — |
| | (A4) | — | — | — | — | — | — | — |
| | (A5) | — | — | — | — | — | — | — |
| | (A6) | — | — | — | — | — | — | 51 |
| (B) | (B1) | 22 | — | — | — | 22 | — | — |
| | (B2) | — | — | — | 22 | — | — | — |
| | (B3) | — | 29 | — | — | — | — | 24 |
| | (B4) | — | — | — | — | — | 24 | — |
| | (B5) | — | — | 40 | — | — | — | — |
| | (B6) | — | — | — | — | — | — | — |
| (C) | (C1) | 20 | 14 | 17 | 25 | — | 20 | — |
| | (C2) | — | — | — | — | — | — | 22 |
| | (C3) | — | — | — | — | 20 | — | — |
| | (C4) | — | — | — | — | — | — | — |

| | | | | | | | |
|---|---|---|---|---|---|---|---|
| (D) | 3 | 3 | 3 | 3 | 3 | 3 | 3 |
| Dielectric | 2.58 | 2.49 | 2.45 | 2.53 | 2.68 | 2.48 | 2.45 |
| constant | | | | | | | |
| Viscosity | 19.2 | 17.6 | 18.2 | 22.6 | 21.2 | 20.1 | 18.2 |
| Inkjet | ○ | ○ | ○ | ○ | ○ | ○ | ○ |
| processability | | | | | | | |
| Photocuring rate | 92.4 | 93.5 | 92.2 | 93.6 | 92.1 | 93.4 | 91.2 |
| Pencil hardness | 3B | 3B | 4B | 3B | 3B | 3B | 4B |

TABLE 2

| | | | | | Compar- | Compar- | Compar- | Compar- |
|---|---|---|---|---|---|---|---|---|
| | | Example | Example | Example | ative | ative | ative | ative |
| | | 8 | 9 | 10 | Example 1 | Example 2 | Example 3 | Example 4 |
| (A) | (A1) | — | — | — | — | 55 | — | — |
| | (A2) | 39 | 38 | — | — | — | — | 10 |
| | (A3) | — | — | — | — | — | — | — |
| | (A4) | — | — | — | 62 | — | — | — |
| | (A5) | — | — | 48 | — | — | — | — |
| | (A6) | — | — | — | — | — | — | — |
| (B) | (B1) | — | — | — | 35 | 22 | — | 67 |
| | (B2) | — | — | — | — | — | 77 | — |
| | (B3) | — | — | 29 | — | — | — | — |
| | (B4) | 29 | — | — | — | — | — | — |
| | (B5) | — | — | — | — | — | — | — |
| | (B6) | — | 25 | — | — | — | — | — |
| (C) | (C1) | 29 | 34 | — | — | — | — | 20 |
| | (C2) | — | — | 20 | — | — | — | — |
| | (C3) | — | — | — | — | — | — | — |
| | (C4) | — | — | — | — | 20 | 20 | — |

| | | | | | | | |
|---|---|---|---|---|---|---|---|
| (D) | 3 | 3 | 3 | 3 | 3 | 3 | 3 |
| Dielectric | 2.50 | 2.80 | 2.60 | 3.05 | 2.95 | — | 2.57 |
| constant | | | | | | | |
| Viscosity | 22.6 | 17.2 | 21.1 | 19.8 | 26.8 | 17.5 | 16.5 |
| Inkjet | ○ | ○ | ○ | ○ | x | x | ○ |
| processability | | | | | | | |
| Photocuring rate | 92.6 | 91.2 | 90.8 | 93.6 | 91.2 | Not cured | 75.8 |
| Pencil hardness | 3B | B | B | B | 2B | — | 6B |

As shown in Table 1, the compositions for encapsulation of an organic light emitting device according to the present invention formed organic layers each having significantly low dielectric constant over a broad frequency range after curing, had good inkjet processability and high photocuring rate, and realized an organic layer having good post-curing pencil hardness.

It should be understood that various modifications, changes, alterations, and equivalent embodiments may be made by those skilled in the art without departing from the spirit and scope of the invention.

1. A composition for encapsulation of an organic light emitting device, comprising: (A) a photocurable polyfunctional monomer; (B) a photocurable monofunctional monomer; (C) a silsesquioxane having one or two photocurable functional groups and at least one substituted or unsubstituted alkyl group; and (D) a photopolymerization initiator,
wherein the composition includes, based on the sum total of 100 parts by weight of (A), (B), (C), and (D),
20 parts by weight to 70 parts by weight of (A),
10 parts by weight to 60 parts by weight of (B), and
5 parts by weight to 50 parts by weight of (C).

2. The composition for encapsulation of an organic light emitting device as claimed in claim 1, wherein;
the silsesquioxane (C) is represented by Formula 5, 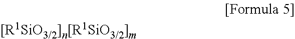
in Formula 5,
R² is a substituted or unsubstituted C₁ to C₂₀ straight or branched alkyl group,
R¹ is represented by Formula 6, 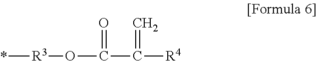
in Formula 6,
* is a linking site to silicon,
R³ is a substituted or unsubstituted C₁ to C₁₀ alkylene group,
R⁴ is hydrogen or a methyl group,
n is an integer of 1 or 2, and
m is an integer of greater than 0 and less than or equal to 10.

3. The composition for encapsulation of an organic light emitting device as claimed in claim 2, wherein:
the silsesquioxane (C) has a polyhedral oligomeric silsesquioxane (POSS) structure represented by Formula 7, 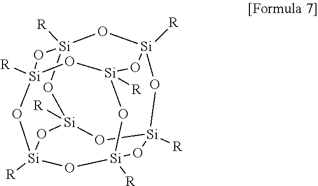
in Formula 7,
one or two Rs are R¹, and
six to seven Rs are R² and
R¹ and R² are each defined the same as those of Formula 5.

4. The composition for encapsulation of an organic light emitting device as claimed in claim 2, wherein, in Formula 5, R² is an isobutyl group, a neopentyl group, an isooctyl group, a 2,4,4-trimethylpentyl group, a dodecyl group, an octadecyl group, or an isooctadecyl group.

5. The composition for encapsulation of an organic light emitting device as claimed in claim 1, wherein the photocurable polyfunctional monomer (A) is present in an amount of 50 parts by weight to 450 parts by weight, relative to 100 parts by weight of the silsesquioxane (C).

6. The composition for encapsulation of an organic light emitting device as claimed in claim 1, wherein the photocurable polyfunctional monomer (A) includes a silicone-free photocurable polyfunctional monomer or a silicone-based photocurable polyfunctional monomer.

7. The composition for encapsulation of an organic light emitting device as claimed in claim 6, wherein the silicone-free photocurable polyfunctional monomer includes bi- to deca-functional (meth)acrylates.

8. The composition for encapsulation of an organic light emitting device as claimed in claim 6, wherein;
the silicone-based photocurable polyfunctional monomer is represented by Formula 1, 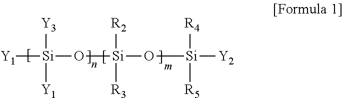
in Formula 1,
R₁, R₂, R₃, R₄, and R₅ are each independently hydrogen, a substituted or unsubstituted C₁ to C₃₀ alkyl group, a substituted or unsubstituted C₁ to C₃₀ alkyl ether group, *—N(R′)(R″) (* being a linking site of an element, R′ and R″ being identical to or different from each other and each independently being hydrogen or a substituted or unsubstituted C₁ to C₃₀ alkyl group), a substituted or unsubstituted C₁ to C₃₀ alkyl sulfide group, a substituted or unsubstituted C₆ to C₃₀ aryl group, or a substituted or unsubstituted C₇ to C₃₀ arylalkyl group,
Y₁, Y₂, and Y₃ are each independently a substituted or unsubstituted C₁ to C₃₀ alkyl group, a substituted or unsubstituted C₁ to C₁₀ monoalkylsilyloxy group, a substituted or unsubstituted C₁ to C₁₀ dialkylsilyloxy group, a substituted or unsubstituted C₁ to C₁₀ trialkylsilyloxy group, or a compound represented by Formula 2, 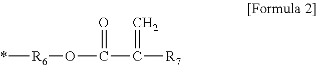
in Formula 2,
* is a linking site of an element,
R₆ is a substituted or unsubstituted C₁ to C₁₀ alkylene group, and
R₇ is hydrogen or a methyl group,
n is an integer of 0 to 20, m is an integer of 0 to 20, and n+m is an integer greater than 0,
Y₁ and Y₂ being the compound represented by Formula 2, or
Y₃ being the compound represented by Formula 2 and n being an integer of 2 to 10.

9. The composition for encapsulation of an organic light emitting device as claimed in claim 8, wherein:
the silicone-based photocurable polyfunctional monomer includes at least one compound represented by Formulas 1-1, 1-2, or 1-3, 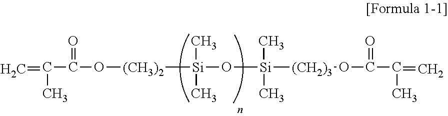
in Formula 1-1, R₇ is hydrogen or a methyl group and n is an integer of 0 to 20, 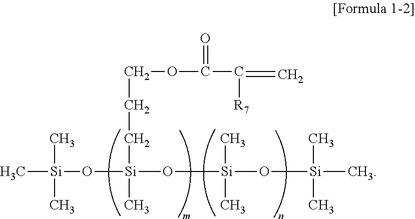
in Formula 1-2, R₇ is hydrogen or a methyl group, n is an integer of 2 to 10, and m is an integer of 0 to 20, 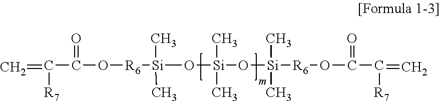
n Formula 1-3, R₆ is a substituted or unsubstituted C₁ to C₁₀ alkylene group, R₇ is hydrogen or a methyl group, and m is an integer of 0 to 20.

10. The composition for encapsulation of an organic light emitting device as claimed in claim 1, wherein the photocurable monofunctional monomer (B) includes a silicone-free photocurable monofunctional monomer or a silicone-based photocurable monofunctional monomer.

11. The composition for encapsulation of an organic light emitting device as claimed in claim 10, wherein the silicone-free photocurable monofunctional monomer includes a mono(meth)acrylate having a substituted or unsubstituted C₁ to C₂₀ straight or branched alkyl group.

12. The composition for encapsulation of an organic light emitting device as claimed in claim 10, wherein the silicone-based photocurable monofunctional monomer is represented by Formula 3, 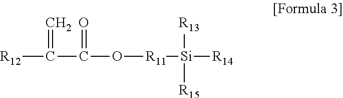
in Formula 3,
R₁ is a single bond or a substituted or unsubstituted C₁ to C₁₀ alkylene group,
R₁₂ is hydrogen or a methyl group, and
R₁₃, R₁₄, and R₁₅ are each independently hydrogen, a substituted or unsubstituted C₁ to C₃₀ alkyl group, a substituted or unsubstituted C₁ to C₃₀ alkyl ether, *—N(R′)(R″) (* being a linking site of an element, R′ and R″ being identical to or different from each other and each independently being hydrogen or a substituted or unsubstituted C₁ to C₃₀ alkyl group), a substituted or unsubstituted C₁ to C₃₀ alkyl sulfide group, a substituted or unsubstituted C₆ to C₃₀ aryl group, a substituted or unsubstituted C₇ to C₃₀ arylalkyl group, a substituted or unsubstituted C₁ to C₁₀ monoalkylsilyloxy group, a substituted or unsubstituted C₁ to C₁₀ dialkylsilyloxy group, a substituted or unsubstituted C₁ to C₁₀ trialkylsilyloxy group, a substituted or unsubstituted C₁ to C₁₀ monoalkylsilyl group, a substituted or unsubstituted C₁ to C₁₀ dialkylsilyl group, a substituted or unsubstituted C₁ to C₁₀ trialkylsilyl group, or a compound represented by Formula 4, 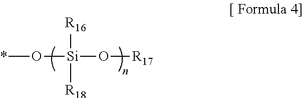
in Formula 4,
is a linking site of an element,
R₁₆, R₁₇, and R₁₈ are each independently hydrogen, a substituted or unsubstituted C₁ to C₁₀ alkyl group, a substituted or unsubstituted C₁ to C₁₀ monoalkylsilyl group, a substituted or unsubstituted C₁ to C₁₀ dialkylsilyl group, a substituted or unsubstituted C₁ to C₁₀ trialkylsilyl group, a substituted or unsubstituted C₁ to C₁₀ monoalkylsilyloxy group, a substituted or unsubstituted C₁ to C₁₀ dialkylsilyloxy group, or a substituted or unsubstituted C₁ to C₁₀ trialkylsilyloxy group, and
n is an integer of 1 to 20.

13. The composition for encapsulation of an organic light emitting device as claimed in claim 12, wherein:
the silicone-based photocurable monofunctional monomer includes a compound represented by Formulas 3-1 to 3-4, 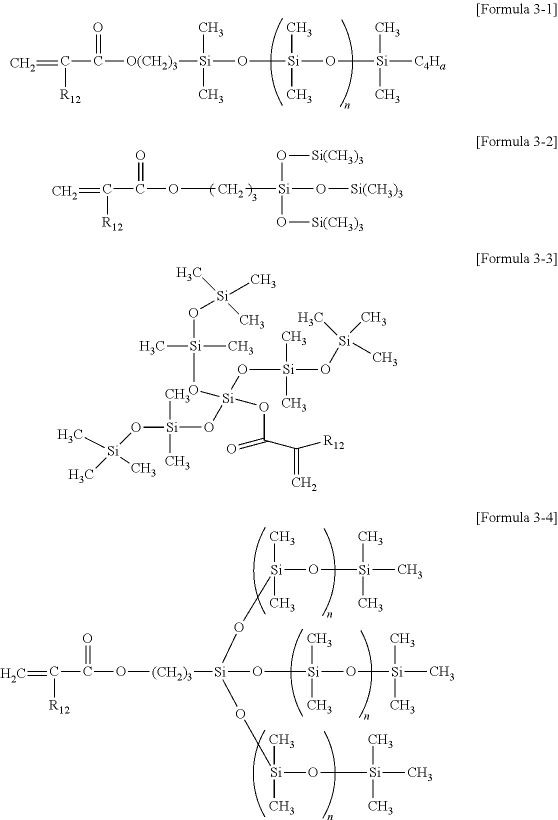
in Formulas 3-1 to 3-4, R₁₂ and n are defined the same as in Formulas 3 and 4.

14. The composition for encapsulation of an organic light emitting device as claimed in claim 1, wherein the composition includes 1 part by weight to 5 parts of (D), based on the sum total of 100 parts by weight of (A), (B), (C), and (D).

15. An organic light emitting device display comprising an organic layer formed of the composition for encapsulation of an organic light emitting device as claimed in claim 1.
